(19) United States
(12) Patent Application Publication
(10) Pub. No.: US 2013/0241579 A1
(43) Pub. Date: Sep. 19, 2013

(54) INPUT DEVICE

(71) Applicant: ALPS ELECTRIC CO., LTD., Tokyo (JP)

(72) Inventor: Akihiro Takahashi, Miyagi-Ken (JP)

(73) Assignee: Alps Electric Co., Ltd., Tokyo (JP)

(21) Appl. No.: 13/777,347

(22) Filed: Feb. 26, 2013

(30) Foreign Application Priority Data
Mar. 14, 2012 (JP) 2012-0057418

(51) Int. Cl. G01R 27/26

(52) U.S. Cl. CPC G01R 27/2605
USPC 324/663

(57) ABSTRACT

An input device includes a capacitive sensor, which detects an operator's approach or touch and an operating body which is movably supported with respect to the capacitive sensor. At least a portion of the operating body has a conductive material portion exposed to a surface, a capacitive coupling portion opposing the conductive material portion regardless of the movement of the operating body is provided on the side unmovable with respect to the capacitive sensor, and the capacitive coupling portion is grounded.

### CLAIM OF PRIORITY

This application claims benefit of Japanese Patent Application No. 2012-057418 filed on Mar. 14, 2012, which is hereby incorporated by reference in its entirety.

### BACKGROUND OF THE DISCLOSURE

1. Field of the Disclosure

The present disclosure relates to an input device having an operating body capable of at least a rotating operation, and in particular to an input device provided with a capacitive sensor which detects an operator's approach to or touch on the rear surface side of the operating body.

2. Description of the Related Art

As an input device provided on a center console of vehicles and the like, there is a known device which performs an input together with a rotating operation of a operating body using an operator's approach or touch with respect to a top side portion of the operating body, in such a manner that the operating body capable of the rotating operation with respect to a base member is provided, the operating body is formed in a bottomed cylinder shape which has the top side portion, and a capacitive sensor which detects the operator's approach or touch with respect to the top side portion is provided on the rear surface side of the top side portion configuring the operating body. Such an input device may include the one disclosed in PCT Japanese Translation Patent Publication No. 2011-526385.

An enhanced design for an input device can be realized using metal plating on an operating body made of resin materials, by allowing at least a portion of the surface of the operating body to have a metallic appearance. However, if the operating body has a metal portion, an operator's touch on the metal portion affects the operation of a capacitive sensor. This is because the capacitance value between the metal portion having conductivity and the ground is changed from an extremely small state to a state passing through the human body and consequently affects the capacitance value of the capacitive sensor as well, which may lead to a malfunction of the capacitive sensor.

Originally, this matter can be avoided by constantly grounding the metal portion formed on the operating body. However, it is difficult to constantly ground the metal portion formed on the operating body capable of a rotating operation with respect to a base member. Therefore, in the input device having the capacitive sensor, the metal portion could not have been formed for the operating body capable of the rotating operation. In addition, without being limited to the rotating operation, even the operating body freely movable with respect to the capacitive sensor has the similar problem.

### SUMMARY

An input device includes a capacitive sensor which detects an operator's approach or touch; and an operating body which is movably supported with respect to the capacitive sensor.

The operating body is arranged so as to surround the capacitive sensor, at least a portion of the operating body has a conductive material portion exposed to a surface, and a base member unmovable with respect to the capacitive sensor has a capacitive coupling portion opposing the conductive material portion and the capacitive coupling portion is grounded.

### BRIEF DESCRIPTION OF THE DRAWINGS

FIG. 1 is a front view of a center console having an input device according to an embodiment.

FIG. 2 is an enlarged view of an input device portion in the cross section A-A in FIG. 1.

FIG. 3 is an enlarged view of an input device portion in the cross section B-B in FIG. 1.

FIG. 4 is an exploded perspective view of an operating body, a base member, a capacitive sensor, a flexible substrate, a first substrate, a second substrate and a rotating support member.

FIG. 5 is a schematic plan view illustrating the positional relationship of a capacitive sensor, a conductive material portion and a capacitive coupling portion.

### DESCRIPTION OF THE EXEMPLARY EMBODIMENTS

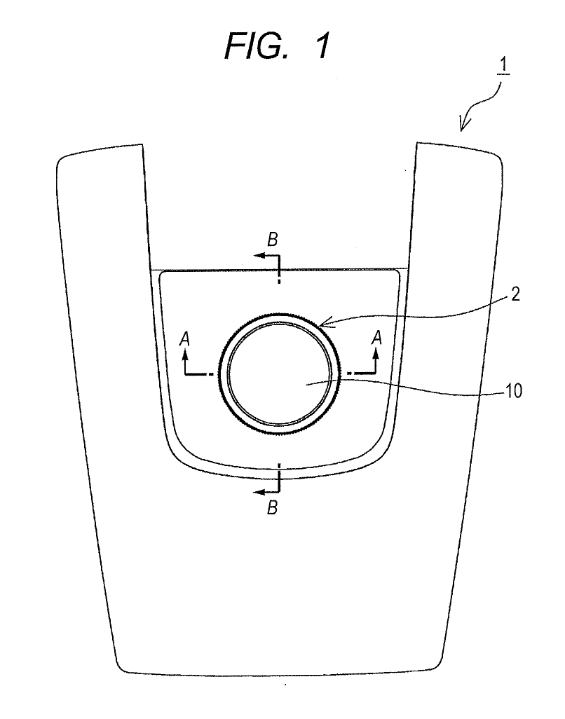

Embodiments of the present invention will be described in detail with reference to the accompanying drawings. FIG. 1 illustrates a front view of a center console 1 having an input device 2 according to an embodiment. The center console 1 is arranged between the driver's seat and the front passenger's seat, and the input device 2 performing various inputs is arranged on the surface thereof.

The input device 2 of the present embodiment is configured such that an operating body 10 having a bottomed cylinder shape is exposed inside a vehicle, the operating body 10 is capable of a rotating operation along the circumferential direction, and additionally capable of a pressing operation in the direction perpendicular to the surface of the center console 1, and a capacitive sensor 15 provided on the rear side of a top side portion 10a can detect the approach or touch of the operator's fingers with respect to the surface of the top side portion 10a of the operating body 10.

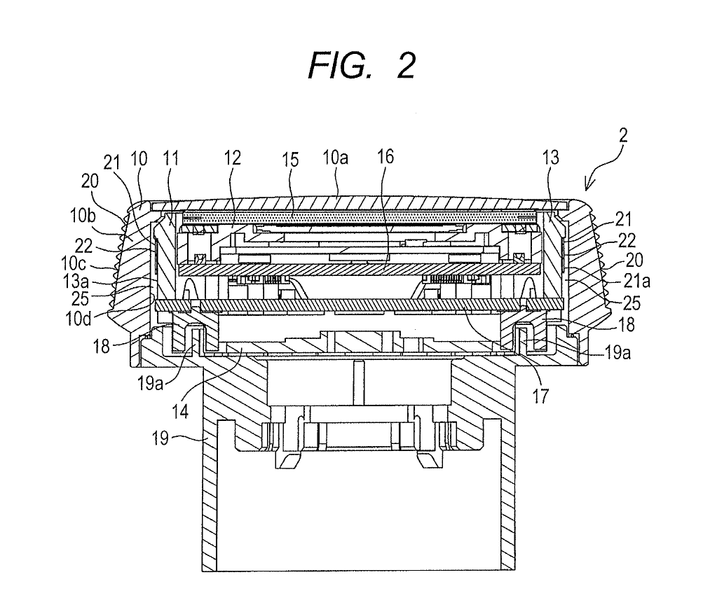

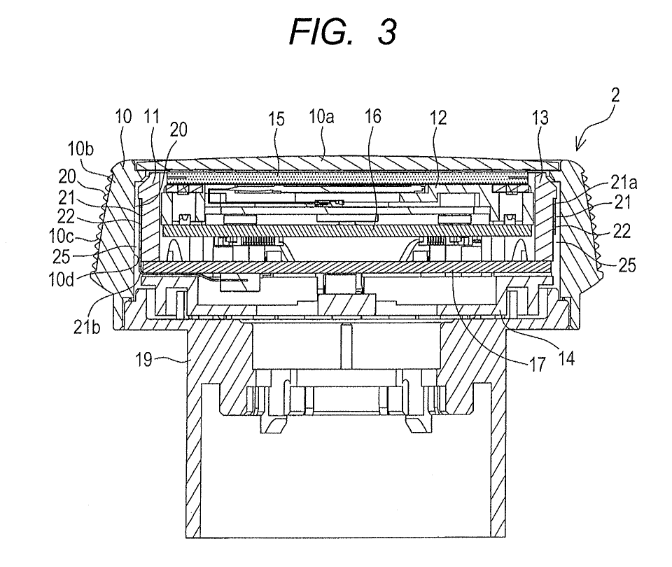

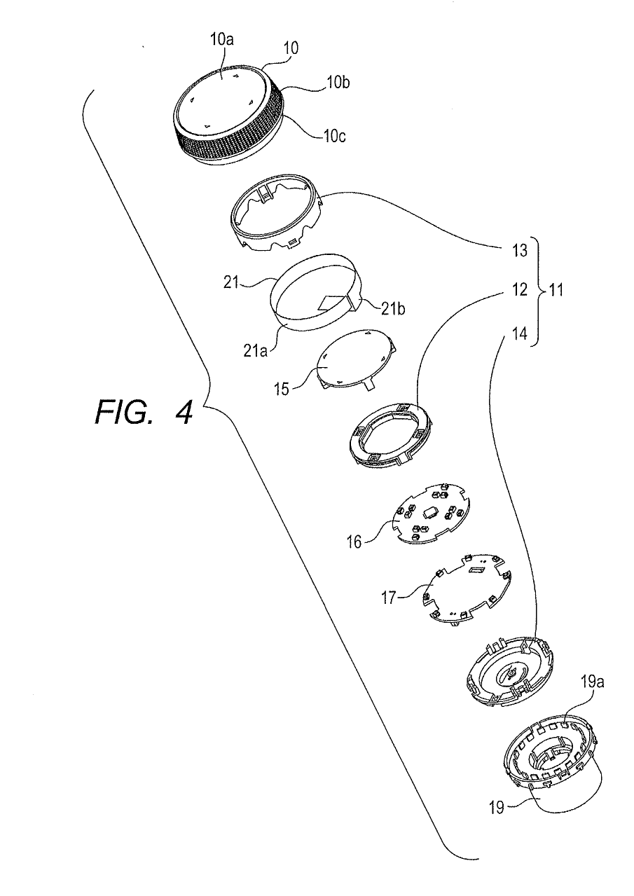

Respectively, FIG. 2 illustrates an enlarged view of the input device 2 portion in the cross section A-A in FIG. 1, FIG. 3 illustrates an enlarged view of the input device 2 portion in the cross section B-B in FIG. 1, and FIG. 4 illustrates an exploded perspective view of the operating body 10, a base member 11, the capacitive sensor 15, a flexible substrate 21, s first substrate 16, a second substrate 17 and a rotating support member 19. The input device 2 is configured by the base member 11 fixed to the vehicle and supporting the capacitive sensor 15, and the operating body 10 supported so as to be rotatably movable with respect to the base member 11. That is, the operating body 10 configures a side rotatably movable with respect to the capacitive sensor 15, and the base member 11 configures a side not rotatably movable with respect to the capacitive sensor 15. Here, the base member 11 holds the capacitive sensor 15 by means not illustrated.

The base member 11 configuring the side not rotatably movable with respect to the capacitive sensor 15 is formed of three components of a support portion 12, a cylindrical portion 13 and a bottom surface portion 14. The support portion 12 supports the capacitive sensor 15 on the upper surface side and is formed so as to have a substantially ring shape. The cylindrical portion 13 is formed so as to have a substantially columnar shape and the capacitive sensor 15 is in a housed state in the upper end portion of the inner peripheral surface thereof.

The first substrate 16 is fixed to the lower surface side of the support portion 12. In addition, the second substrate 17 is fixed below the first substrate 16. Electrical components required for operating the capacitive sensor 15, a light emitter emitting light during the operation or the like are arranged on the first substrate 16. The electrical components or the like for detecting the rotation of the operating body 10 are arranged on the second substrate 17. The bottom surface 14 supports the lower surface side of the second substrate 17 and is formed so as to have a substantially disk shape.

The rotating support member 19 rotatable together with the operating body 10 is arranged at the lower portion of the bottom surface portion 14. The rotating support member 19 is rotatably supported with respect to the vehicle and is fixedly fitted to the operating body 10. That is, the rotating support member 19 configures the side rotatably movable with respect to the capacitive sensor 15. The rotating support member 19 has convex portions 19a on its upper surface. The convex portions 19a are plurally formed along the circumferential direction of the rotating support member 19.

As illustrated in FIG. 2, a rotating detection portion 18 with a concave cross section is provided at two places of the lower surface side of the second substrate 17 and is arranged so as to insert the convex portions 19a of the rotating support member 19 to the rotating detection portion 18. The rotating detection portion 18, where optical sensors are arranged on both inner side surfaces with a concave shape, can detect that the rotating support member 19 is rotated together with the operating body 10 and the convex portions 19a passes through the inside of the rotating detection portion 18. During the rotation of the rotating support member 19, the convex portions 19a are arranged so as to pass through each rotating detection portion 18 at a different timing, and the rotating direction of the rotating body 10 can be determined from a phase difference of detected signals. In addition, it is possible to detect the rotation amount of the operating body 10 by counting the number of passes of the convex portions 19a.

The cylindrical portion 13 configuring the base member 11 allows the inside thereof to accommodate the capacitive sensor 15 and the first substrate 16, and the second substrate 17 are arranged at the lower surface side thereof. Then, the operating body 10 is arranged so as to surround the outer peripheral surface 13a of the cylindrical portion 13 and the capacitive sensor 15.

The operating body 10 includes the top side portion 10a and the lateral side portion 10b configuring in a cylindrical shape. A plurality of irregularities is formed on the lateral side portion 10b along the circumferential direction to facilitate the rotating operation for the operator. In the present embodiment, the top side portion 10a and the lateral side portion 10b are configured as separate components. However, they may be integrated. The clearance gap portion 25 spaced over the entire periphery is formed between the inner peripheral surface 10d of the lateral side portion 10b and the outer peripheral surface 13a of the cylindrical portion 13.

The operating body 10 is formed from a resin material, but metal plating is applied to the surface of the lateral side portion 10b. The metal plating is formed over the entire surface of the outer peripheral surface 10c and the inner peripheral surface 10d of the lateral side portion 10b, which configures a conductive material portion 20 exposed to the surface, in the operating body 10, which is the side rotatably movable with respect to the capacitive sensor 15.

In the clearance gap portion 25 formed between the base member 11 and the operating body 10, on the outer peripheral surface 13a of the cylindrical portion 13, which opposes the inner peripheral surface 10d of the operating body 10, a capacitive coupling portion 22 in capacitive coupling with the conductive material portion 20 is provided along the circumferential direction. The capacitive coupling portion 22 is formed as a conductive pattern on a flexible substrate 21 which is freely deformable with flexibility, and is arranged at the side not rotatably movable with respect to the capacitive sensor 15, proximately opposing the conductive material portion 20 of the operating body 10. In addition, since the capacitive coupling portion 22 is provided over the entire periphery of the cylindrical portion 13, regardless of the rotating movement of the rotating body 10, the capacitive coupling portion 22 opposes the conductive material portion 20 in a constant distance. In addition, the capacitive coupling portion may not be in the conductive pattern, and may be the one which can be capacitively coupled with the conductive material portion 20.

As illustrated in FIG. 4, the flexible substrate 21 includes a winding portion 21a, which forms a ring shape along the outer peripheral surface 13a of the cylindrical portion 13, and an extending portion 21b, which is extended from one end portion of the winding portion 21a toward the second substrate 17 side. Then, the capacitive coupling portion 22 formed of the continuous conductive pattern from the winding portion 21a to the extending portion 21b is formed on the surface thereof.

In FIG. 3, the extending portion 21b of the flexible substrate 21 is illustrated. The extending portion 21b is drawn from the outer peripheral surface 13a of the cylindrical portion 13 to the lower surface side of the second substrate 17, and the end portion thereof is inserted and fixed with respect to the bottom surface portion 14. The capacitive coupling portion 22 of the extending portion 21b is conductively in contact with a ground terminal of the second substrate 17, and is in a state of being grounded in the input device 2.

The capacitive sensor 15 is configured such that two electrodes proximately opposing each other forms one pair and multiple pairs of the electrodes are respectively arranged along two directions orthogonal to each other. Then, the capacitive sensor 15 can detect the presence or absence of the operation and operating places by detecting capacitance between the electrodes which is changed due to the approach or touch of the operator's fingers on the surface of the capacitive sensor 15.

Here, in a case where the conductive material of the grounding object is present in the vicinity of the capacitive sensor 15, the conductive material is coupled with the ground with very small amount of stray capacitance. However, if the user touches the conductive material, a capacitance value between the conductive material and the ground is changed to a state passing through the human body and consequently the changed capacitance value also causes the change of the capacitance in the capacitive sensor 15. Accordingly, there is a possibility that the capacitive sensor 15 may erroneously detect the operation. By keeping a sufficiently larger capacitive coupling in advance between the conductive material and the ground than the capacitance value between the conductive material and the capacitive sensor 15, it is possible to suppress the change of the capacitance in the capacitive sensor 15 when the operator touches the conductive material.

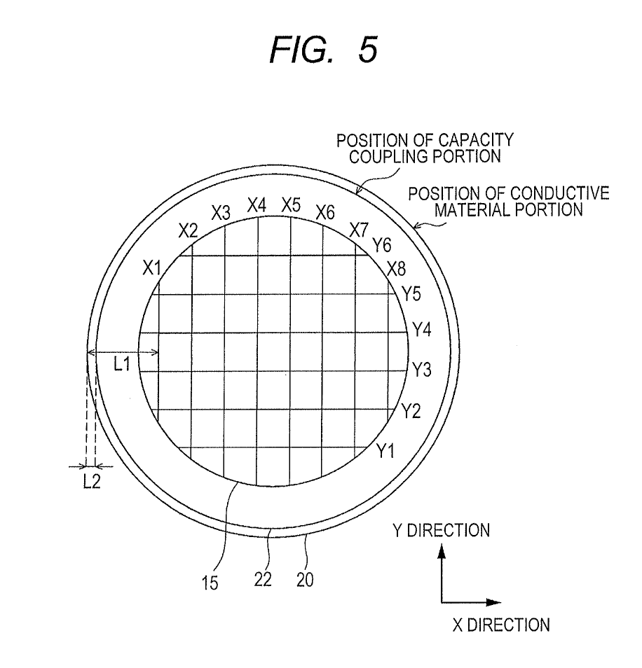

In the present embodiment, the conductive material portion 20 formed on the surface of the operating body 10 corresponds to the conductive material, which is present in the vicinity of the capacitive sensor 15. The operator's touching on this leads to in the change of the capacitance in the capacitive sensor 15. Therefore, the capacitive coupling portion 22 capacitively coupled with the conductive material portion 20 is provided on the base member 11, which is grounded. FIG. 5 is a schematic plan view illustrating the positional relationship of the capacitive sensor 15, the conductive material portion 20 and the capacitive coupling portion 22.

In FIGS. 5, X1 to X8 represent the electrodes arranged along the direction X of the drawing and Y1 to Y6 represent the electrodes arranged along the direction Y of the drawing. In this manner, the electrodes detecting the capacitance value are arrayed to form a lattice pattern on the surface of the capacitive sensor 15.

The electrode of the capacitive sensor 15, which is closest to the conductive material portion 20, represents X1 and the distance from this to the conductive material portion 20 represents L1. On the other hand, the capacitive coupling portion 22 is formed on the outer peripheral surface 13a of the cylindrical portion 13 proximately opposing the inner peripheral surface 10d of the operating body 10, on which the conductive material portion 20 is formed, and the distance from the conductive material portion 20 represents L2, which is shorter than L1.

In addition, the electrode of the capacitive sensor 15 is formed with a very small diameter. Accordingly, an area S1 opposing the conductive material portion 20 is small. In contrast, the capacitive coupling portion 22 is formed to fit the width of the flexible substrate 21 and thereby the area S2 opposing the conductive material portion 20 is larger than S1.

The capacitance value C of the electrodes opposing each other can be expressed by “Capacitance Value C=εS/L”. In other words, the capacitance value C is proportional to an opposing area S of the two and is inversely proportional to a distance L. Accordingly, the capacitance value C1 of the conductive material portion 20 and the capacitive coupling portion 22, in which the opposing area S2 is large and the distance L2 is short, comes to have the small opposing area S1, and becomes larger than the capacitance value C2 of the conductive material portion 20 and the capacitive sensor 15, in which the opposing area S1 is small and the distance L1 is long.

In this way, the operating body 10 having the conductive material portion 20 on its surface is movably provided with respect to the capacitive sensor 15, and the capacitive coupling portion 22 opposing the conductive material portion 20 regardless of the movement of the operating body 10 is provided on the base member 11 which is the side not movable with respect to the capacitive sensor 15. By the capacitive coupling portion 22 being grounded, even if the metal portion is provided on the rotating body 10, the influence due to capacitance fluctuations applied to the capacitive sensor 15 can be decreased and thereby malfunction of the capacitive sensor 15 can be prevented.

In the present embodiment, the cylindrical portion 13 is provided on the base member 11 and the capacitive coupling portion 22 is provided on the outer peripheral surface 13a of the cylindrical portion 13. However, the configuration may not include the cylindrical portion 13 in the base member 11. In any case, even in such a manner that the clearance gap portion is formed between the side not movable with respect to the capacitive sensor and the conductive material portion provided on the operating body, and the capacitive coupling portion is provided in the clearance gap portion, the capacitive coupling portion may be configured to oppose the conductive material portion.

In addition, in the present embodiment, the capacitive coupling portion 22 is provided on the outer peripheral surface 13a of the cylindrical portion 13. However, if the capacitance value C1 of the conductive material portion 20 and the capacitive coupling portion 22 can be sufficiently secured compared to the capacitance value C2 of the conductive material portion 20 and the capacitive sensor 15, the capacitive coupling portion may be provided along the lateral surface of the capacitive sensor 15, alternatively, along the lateral surface of the first substrate 16 or the second substrate 17.

The operating body 10 is not limited to the one which is freely rotatable. A sliding or swinging one may be adopted. Even in those cases, it is possible to suppress the influence with respect to the capacitive sensor by providing and grounding the capacitive coupling portion opposing the conductive material portion on the side not movable with respect to the capacitive sensor.

Hitherto, the embodiment of the present invention has been described, but an application of the present invention is not limited to the present embodiment, and the present invention may be variously adopted within the scope of the technical spirit thereof.

It should be understood by those skilled in the art that various modifications, combinations, sub-combinations and alterations may occur depending on design requirements and other factors insofar as they are within the scope of the appended claims of the equivalents thereof.

What is claimed is:

1. An input device, comprising:
a capacitive sensor which detects an operator's approach or touch; and
an operating body which is movably supported with respect to the capacitive sensor,
wherein the operating body surrounds the capacitive sensor,
wherein at least a portion of the operating body has a conductive material portion exposed to a surface, and
wherein a base member unmovable with respect to the capacitive sensor has a capacitive coupling portion opposing the conductive material portion and the capacitive coupling portion is grounded.

2. The input device according to claim 1,
wherein the capacitive sensor is attached to the base member, the operating body has a bottomed cylinder shape having a top side portion and a lateral side portion, and the top side portion and the capacitive sensor oppose each other, and
wherein the conductive material portion is disposed on the lateral side portion of the operating body, a clearance gap portion is formed between the lateral side portion and the base member, and the capacitive coupling portion is provided on the base member so as to face the clearance gap portion.

3. The input device according to claim 2,
wherein the base member has a cylindrical portion, the outer peripheral surface of the cylindrical portion and the inner peripheral surface of the lateral side portion oppose each other, and the capacitive coupling portion is provided along the outer peripheral surface of the cylindrical portion.

4. The input device according to claim 3,
wherein a flexible substrate is arranged along the outer peripheral surface of the cylindrical portion and the capacitive coupling portion is formed on the flexible substrate.

5. The input device according to claim 2,
wherein the capacitive coupling portion is provided along the lateral surface of the capacitive sensor.
